(19) United States
(12) Patent Application Publication
(10) Pub. No.: US 2025/0042654 A1
(43) Pub. Date: Feb. 6, 2025

(54) LOGISTICS HANDLING APPARATUS AND INSTALLATION METHOD THEREOF

(71) Applicant: SEMES CO., LTD., Chungcheongnam-do (KR)

(72) Inventor: Young Eun LEE, Gyeonggi-do (KR)

(21) Appl. No.: 18/772,112

(22) Filed: Jul. 13, 2024

(30) Foreign Application Priority Data
Jul. 31, 2023 (KR) 10-2023-0099329

(51) Int. Cl. B65G 1/04

(52) U.S. Cl. CPC B65G 1/0464

(57) ABSTRACT

A logistics handling apparatus and an installation method thereof are provided. The logistics handling apparatus includes: an upper structure provided within a line; a Side Track Buffer (STB) installed on the upper structure; and a connecting structure coupling the STB and the upper structure together, wherein the connecting structure and the upper structure are coupled in a one-touch manner.

### CROSS-REFERENCE TO RELATED APPLICATION

This application claims priority from Korean Patent Application No. 10-2023-0099329 filed on Jul. 31, 2023, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a logistics handling apparatus and an installation method thereof.

### 2. Description of the Related Art

In logistics handling, Side Track Buffers (STBs) are installed using a simple bolt and nut fastening structure, and the amount of labor required for their installation is high. Moreover, only skilled workers are able to work on such STBs. Therefore, it is necessary to devise a method that allows personnel responsible for handling STBs domestically, as well as those handling STBs overseas, to perform their tasks more easily and quickly.

### SUMMARY

According to an aspect of the present disclosure, a logistics handling apparatus includes: an upper structure provided within a line; a Side Track Buffer (STB) installed on the upper structure; and a connecting structure coupling the STB and the upper structure together, wherein the connecting structure and the upper structure are coupled in a one-touch manner.

According to another aspect of the present disclosure, a logistics handling apparatus includes: a controller; an upper structure provided within a line; an STB provided within the line; and a connecting structure coupling the STB and the upper structure together, wherein the connecting structure and the upper structure are coupled in a one-touch manner, the connecting structure is installed on the STB and then moved to a position corresponding to the upper structure to be installed on the upper structure, the connecting structure is equipped with an electromagnet part, and is coupled to the upper structure in a one-touch manner through the electromagnet part, the controller is interlocked with the electromagnet part of the connecting structure, controls a magnetic coupling force of the electromagnet part through power supply, the upper structure includes a mounting plate provided on a ceiling of the line, and the electromagnet part is coupled to the mounting plate.

According to another aspect of the present disclosure, an installation method of a logistics handling apparatus includes: preparing an STB; installing a connecting structure on the STB; moving the STB to a position corresponding to an upper structure; and mounting the STB on the upper structure through the connecting structure.

According to the aforementioned and other embodiments of the present disclosure, there are one or more of the following effects.

First, an effective installation of STBs for logistics handling is possible.

Second, by improving the simple coupling structure of STBs, installation work can be facilitated for workers.

Third, personnel responsible for handling STBs domestically, as well as those handling STBs overseas, are enabled to perform installation work more easily and quickly.

Fourth, from an installation perspective, STBs with a structure that can satisfy adhesion and safety factors with electromagnets can be provided.

Fifth, the labor for installing and dismantling STBs can be reduced (e.g., the installation time per set can be reduced from 20 minutes to 5 minutes).

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram illustrating a logistics handling apparatus according to an embodiment of the present disclosure;

FIG. 2 is a diagram illustrating the configuration of the logistics handling apparatus of FIG. 1;

FIGS. 3 and 4 are diagrams illustrating the installed state of the logistics handling apparatus of FIG. 1;

FIG. 5 is a diagram illustrating the control state of the logistics handling apparatus of FIG. 1;

FIG. 6 is a reference diagram for explaining the logistics handling apparatus of FIG. 1;

FIG. 7 is a reference table for explaining the logistics handling apparatus of FIG. 1; and

FIG. 8 is a flowchart illustrating sequential steps of an installation method of the logistics handling apparatus of FIG. 1.

### DETAILED DESCRIPTION

Hereinafter, exemplary embodiments of the present disclosure will be described in detail with reference to the accompanying drawings. Advantages and features of the present disclosure, and a method for achieving the advantages and features will become apparent with reference to the exemplary embodiments described below in detail in conjunction with the accompanying drawings. However, the present disclosure is not limited to the exemplary embodiments disclosed below but may be implemented in a variety of different forms, these exemplary embodiments will be provided only to make the present disclosure complete and allow those skilled in the art to completely recognize the scope of the present disclosure, and the present disclosure is only defined by the scope of the claims. The same reference numbers indicate the same components throughout the specification.

Spatially relative terms such as “below,” “beneath,” “lower,” “above,” “upper,” etc., can be used to facilitate the description of the relationships between one object or components and another as shown in the drawings. These spatially relative terms should be understood to encompass different orientations of the subject matter in use or operation in addition to the orientation depicted in the drawings. For example, if the subject matter in the drawings is turned over, an object described as “below” or “beneath” another object may be above the other object. Thus, the exemplary term “below” may include both upward and downward directions. Objects may be oriented in other directions, and thus, spatially relative terms may be interpreted according to the orientation.

Although terms like “first,” “second,” etc., are used to describe various objects, components, and/or sections, these objects, components, and/or sections should not be limited by these terms. These terms are only used to distinguish one object, component, or section from another. Therefore, a “first” object, component, or section mentioned below in the technical spirit of the present invention may be a “second” object, component, or section.

Terms used in this specification are for the purpose of describing particular embodiments only and are not intended to be limiting of the present invention. In this specification, singular forms are intended to include plural forms as well, unless the context clearly indicates otherwise. The terms “comprises” and/or “comprising,” when used in this specification, specify the presence of stated features, steps, operations, elements, and/or components, but do not preclude the presence or addition of one or more other features, steps, operations, elements, components, and/or groups thereof. Unless otherwise defined, all terms (including technical and scientific terms) used herein can be understood to have the meaning commonly understood by those of ordinary skill in the art to which this invention pertains. Terms defined in a commonly used dictionary are to be interpreted as having a standard meaning and not overly or excessively interpreted, unless explicitly defined otherwise.

Embodiments of the present invention will hereinafter be described in detail with reference to the attached drawings. Identical or corresponding components are given the same reference numerals, and redundant descriptions thereof will be omitted.

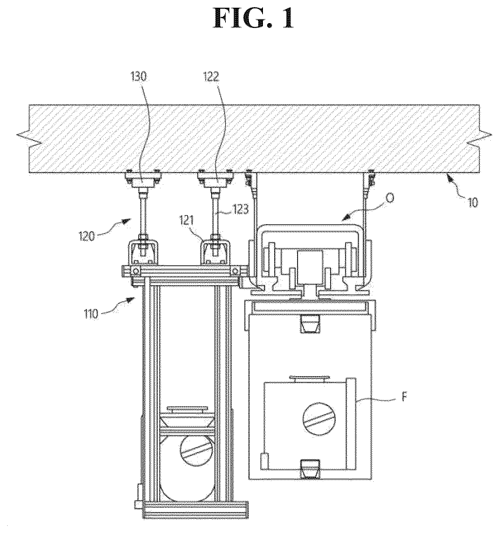

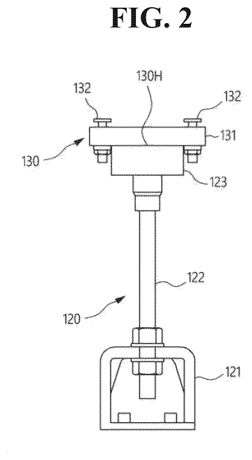

FIG. 1 illustrates a logistics handling apparatus according to an embodiment of the present disclosure. FIG. 2 illustrates the detailed configuration of the logistics handling apparatus of FIG. 1.

Referring to FIGS. 1 and 2, a logistics handling apparatus 100 (hereinafter, referred to as “the apparatus 100”) includes Side Track Buffers (STBs) 110, connecting structures 120, an upper structure 130, and a controller 140.

Each of the connecting structures 120 includes a lower connecting part 121, a middle connecting part 122, and an electromagnet part 123. The upper structure 130 includes a mounting plate 131 and bolting members 132.

Here, the upper structure 130 is provided within a line for logistics handling. A plurality of STBs 110 are installed on the upper structure 130.

The connecting structures 120 couple the STBs 110 and the upper structure 130 together. The connecting structures 120 and the upper structure 130 are coupled in a one-touch manner.

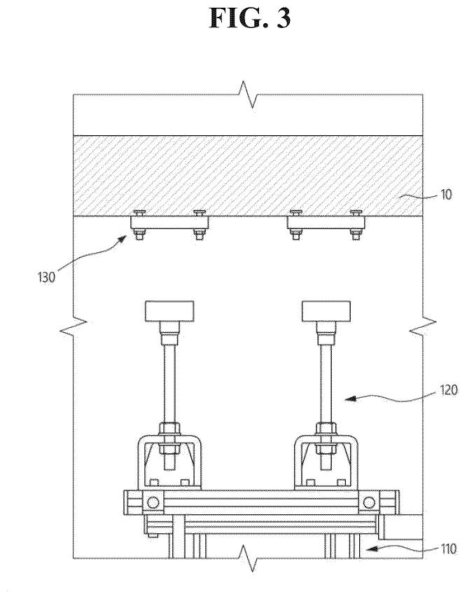

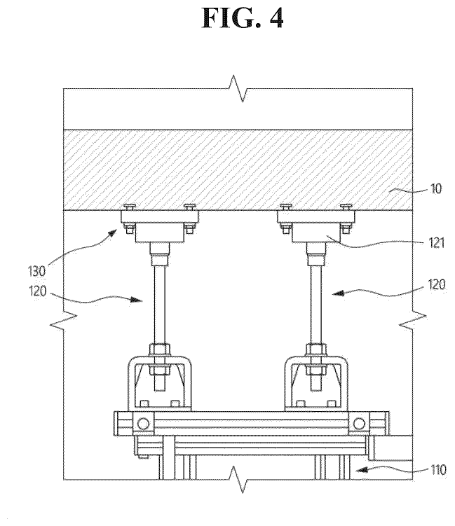

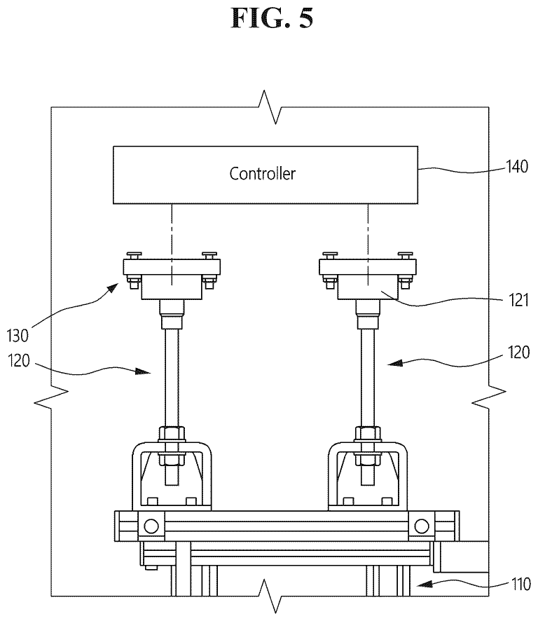

FIGS. 3 and 4 illustrate the installed state of the logistics handling apparatus of FIG. 1. FIG. 5 illustrates the control state of the logistics handling apparatus of FIG. 1.

Referring to FIGS. 3, 4, and 5, the connecting structures 120 are moved to a position corresponding to the upper structure 130 after being installed on the STBs 110, and are then installed on the upper structure 130.

The connecting structures 120 are equipped with the electromagnet parts 123, and are coupled to the upper structure 130 in a one-touch manner through the electromagnet parts 123.

Here, the controller 140 is interlocked to the electromagnet parts 123 of the connecting structures 120 and controls the magnetic coupling force of the electromagnet parts 123 through power supply.

For example, the controller 140 may be installed to be interlocked to the electromagnet parts 123 when the STBs 110 are coupled to the upper structure 130 through the connecting structures 120.

Moreover, the controller 140 acquires in advance a required magnetic coupling force, which is the magnetic coupling force of the electromagnet parts 123 required for coupling the STBs 110 to the upper structure 130 through the connecting structures 120.

Here, the controller 140 acquires a predetermined safety factor information value needed for installing the STBs 110 on the upper structure 130. Then, the controller 140 controls the magnetic coupling force of the electromagnet parts 123 to satisfy the safety factor information value.

Here, the controller 140 may set the magnetic coupling force of the electromagnet parts 123 in stages between minimum and maximum values based on the safety factor information value. The mounting plate 131 of the upper structure 130 is provided on a ceiling 10 of the line.

The electromagnet parts 123 of the upper structure 130 is coupled to the mounting plate 131. The mounting plate 131 is installed on the ceiling 10 of the line through a plurality of bolting members 132 that are spaced apart from each other.

Moreover, the connecting structures 120 may be coupled in a one-touch manner by entering and contacting a spacing 130H between the bolting members 132.

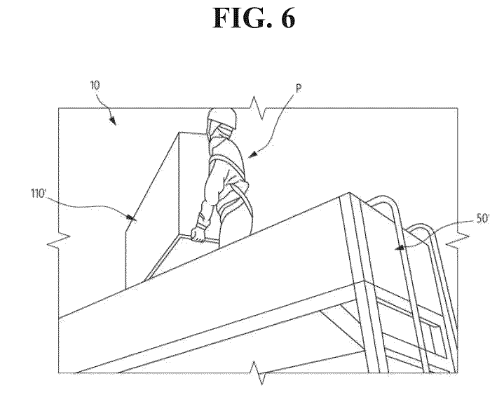

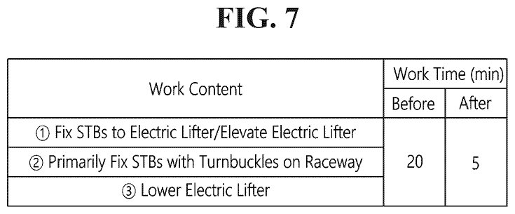

FIG. 6 is a reference diagram for explaining the logistics handling apparatus of FIG. 1. FIG. 7 shows a reference table for explaining the logistics handling apparatus of FIG. 1.

Referring to FIGS. 6 and 7, conventionally, multiple workers may board a lift 50′, holding STBs 110′, and may then install and fasten the STBs 110′ on the ceiling 10 of the line through a simple bolting method, etc.

As a result, there are problems with reduced installation accuracy and extended installation time. Conversely, according to the apparatus 100, the overall processes, including fixing the STBs 110 with an electric lifter, primarily fixing the STBs 110 with turnbuckles on a raceway, lowering the electric lifter, etc., can be significantly reduced compared to an existing logistics handling apparatus.

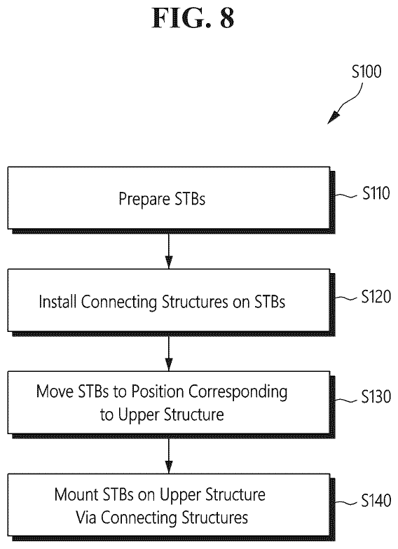

FIG. 8 illustrates sequential steps of an installation method of the logistics handling apparatus of FIG. 1. Referring to FIG. 8, an installation method S100 of the apparatus 100 begins with step S110 where the STBs 110 are prepared. In step S120, the connecting structures 120 are installed on the STBs 110.

In step S130, the STBs 110 are moved to the position corresponding to the upper structure 130. In step S140, the STBs 110 are mounted on the upper structure 130 through the connecting structures 120.

The connecting structures 120 and the upper structure 130 are coupled in a one-touch manner. The connecting structures 120 are equipped with the electromagnet parts 123, and are coupled to the upper structure 130 in a one-touch manner through the electromagnet parts 123.

Furthermore, the controller 140 is interlocked with the electromagnet parts 123 of the connecting structures 120, and controls the magnetic coupling force of the electromagnet parts 123 through power supply.

The controller 140 is installed to be interlocked with the electromagnet parts 123 when the STBs 110 are coupled to the upper structure 130 through the connecting structures 120.

Additionally, the controller 140 acquires in advance the required magnetic coupling force, which is the magnetic coupling force of the electromagnet parts 123 required for coupling the STBs 110 to the upper structure 130 through the connecting structures 120.

The controller 140 acquires a predetermined safety factor information value needed for installing the STBs 110 on the upper structure 130. The controller 140 controls the magnetic coupling force of the electromagnet parts 123 based on the required magnetic coupling force to satisfy the safety factor information value.

Here, the controller 140 may set the magnetic coupling force of the electromagnet parts 123 in stages between the minimum and maximum values based on the safety factor information value. The mounting plate 131 of the upper structure 130 is provided on the ceiling 10 of the line. The electromagnet parts 123 are coupled to the mounting plate 131.

While the embodiments of the present invention have been described with reference to the accompanying drawings, it will be understood by those skilled in the art that the present invention can be implemented in other specific forms without changing the technical spirit or essential features thereof. Therefore, the embodiments described above should be considered in all respects as illustrative and not restrictive.

What is claimed is:

1. A logistics handling apparatus comprising:
an upper structure provided within a line;
a Side Track Buffer (STB) installed on the upper structure; and
a connecting structure coupling the STB and the upper structure together,
wherein the connecting structure and the upper structure are coupled in a one-touch manner.

2. The logistics handling apparatus of claim 1, wherein the connecting structure is installed on the STB and then moved to a position corresponding to the upper structure to be installed on the upper structure.

3. The logistics handling apparatus of claim 1, wherein the connecting structure is equipped with an electromagnet part, and is coupled to the upper structure in a one-touch manner through the electromagnet part.

4. The logistics handling apparatus of claim 3, further comprising:
a controller interlocked with the electromagnet part of the connecting structure, the controller controlling a magnetic coupling force of the electromagnet part through power supply.

5. The logistics handling apparatus of claim 4, wherein the controller is installed to be interlocked with the electromagnet part in a state where the STB is coupled to the upper structure through the connecting structure.

6. The logistics handling apparatus of claim 4, wherein the controller acquires in advance a required magnetic coupling force, which is a magnetic coupling force of the electromagnet part required for coupling the STB to the upper structure through the connecting structure.

7. The logistics handling apparatus of claim 6, wherein the controller acquires a predetermined safety factor information value needed for installing the STB on the upper structure, and controls the magnetic coupling force of the electromagnet part based on the required magnetic coupling force to satisfy the safety factor information value.

8. The logistics handling apparatus of claim 7, wherein the controller sets the magnetic coupling force of the electromagnet part in stages between minimum and maximum values based on the safety factor information value.

9. The logistics handling apparatus of claim 3, wherein
the upper structure includes a mounting plate provided on a ceiling of the line, and
the electromagnet part is coupled to the mounting plate.

10. The logistics handling apparatus of claim 9, wherein
the mounting plate is installed on the ceiling through a plurality of bolting members that are spaced apart from each other, and
the connecting structure is coupled in a one-touch manner by contacting a spacing between the bolting members.

11. A logistics handling apparatus comprising:
a controller;
an upper structure provided within a line;
a Side Track Buffer (STB) provided within the line; and
a connecting structure coupling the STB and the upper structure together,
wherein
the connecting structure and the upper structure are coupled in a one-touch manner,
the connecting structure is installed on the STB and then moved to a position corresponding to the upper structure to be installed on the upper structure,
the connecting structure is equipped with an electromagnet part, and is coupled to the upper structure in a one-touch manner through the electromagnet part,
the controller is interlocked with the electromagnet part of the connecting structure, controls a magnetic coupling force of the electromagnet part through power supply,
the upper structure includes a mounting plate provided on a ceiling of the line, and
the electromagnet part is coupled to the mounting plate.

12. An installation method of a logistics handling apparatus, comprising:
preparing a Side Track Buffer (STB);
installing a connecting structure on the STB;
moving the STB to a position corresponding to an upper structure; and
mounting the STB on the upper structure through the connecting structure.

13. The installation method of claim 12, wherein the connecting structure and the upper structure are coupled in a one-touch manner.

14. The installation method of claim 12, wherein the connecting structure is equipped with an electromagnet part, and is coupled to the upper structure in a one-touch manner through the electromagnet part.

15. The installation method of claim 14, further comprising:
a controller interlocked with the electromagnet part of the connecting structure, the controller controlling a magnetic coupling force of the electromagnet part through power supply.

16. The installation method of claim 15, wherein the controller is installed to be interlocked with the electromagnet part in a state where the STB is coupled to the upper structure through the connecting structure.

17. The installation method of claim 15, wherein the controller acquires in advance a required magnetic coupling force, which is a magnetic coupling force of the electromagnet part required for coupling the STB to the upper structure through the connecting structure.

18. The installation method of claim 17, wherein the controller acquires a predetermined safety factor information value needed for installing the STB on the upper structure, and controls the magnetic coupling force of the electromagnet part based on the required magnetic coupling force to satisfy the safety factor information value.

19. The installation method of claim 18, wherein the controller sets the magnetic coupling force of the electromagnet part in stages between minimum and maximum values based on the safety factor information value.

20. The installation method of claim 18, wherein
the upper structure includes a mounting plate provided on the ceiling of the line, and
the electromagnet part is coupled to the mounting plate.
